(19) United States
(12) Patent Application Publication
(10) Pub. No.: US 2010/0156327 A1
(43) Pub. Date: Jun. 24, 2010

(54) Portable Electronic Device with Touch Illumination Function and Touch Illumination Method Thereof

(75) Inventors: Mu-Tsai Chang, Taipei (TW); Chao-Feng Kang, Taipei (TW); Ming-Tsung Wu, Taipei (TW); Jhung-Ren Huang, Taipei (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: ASUSTEK COMPUTER INC., Taipei (TW)

(21) Appl. No.: 12/512,551

(22) Filed: Jul. 30, 2009

(30) Foreign Application Priority Data
Dec. 22, 2008 (TW) 97150137

(51) Int. Cl. H05B 37/02; H03K 17/96

(52) U.S. Cl. 315/362; 327/517

(57) ABSTRACT

A portable electronic device with a touch illumination function and a touch illumination method thereof are provided. The portable electronic device with the touch illumination function includes an input module, a touch sensor, and an illumination module. The touch sensor is disposed around the input module, senses a touch motion of the input module, and generates a touch signal according to the touch motion. The illumination module is disposed around the input module, coupled with the touch sensor, and controls the illumination module to generate a light source to illuminate the input module according to the touch signal.

### CROSS-REFERENCES TO RELATED APPLICATIONS

This non-provisional application claims priority under 35 U.S.C. §119(a) on Patent Application No. 97150137 filed in Taiwan, R.O.C. on Dec. 22, 2008, the entire contents of which are hereby incorporated by reference.

### BACKGROUND OF THE INVENTION

1. Technical Field

The invention relates to a portable electronic device and an illumination method and, more particularly, to a portable electronic device with a touch illumination function and a touch illumination method thereof.

2. Related Art

As a portable electronic device gradually becomes light, small, and thin, the portable electronic device is more and more popular. A user can enjoy various functions of the portable electronic device anytime and anywhere without a location limitation.

If the portable electronic device is a notebook computer, a keyboard, a function key, or a slot and so on, it may be used as an input module of a computer system. As a result, the user inputs words, symbols and so on via the keyboard, and he inputs a command to enable a corresponding function via the function key. For example, the computer system is booted via a power key. A peripheral device is connected via the slot to allow the peripheral device and the computer system to transfer data to each other.

However, a problem exits in the input module of the notebook computer in the above example. That is, no illumination device assists in lighting the input module. Consequently, when the notebook computer is used at night or at a place without sufficient light, the user may not easily use it.

For example, when the user wants to connect a peripheral device and the notebook computer, without sufficient light, it is difficult for the user to find the correct position of the slot clearly. Thus, he cannot connect the peripheral device with the notebook computer smoothly. Furthermore, when the user wants to boot the notebook computer in the dark, he may not find the power button of function keys and cannot boot the notebook computer smoothly without illuminate light. Additionally, when the user uses the notebook computer to type in an environment without sufficient light, he may be unable to identify letters and symbols on the keyboard due to insufficient ambient brightness, and thus it is uneasy for the user to input words, symbols and so on.

### SUMMARY

The invention provides a portable electronic device with a touch illumination function. The portable electronic device includes an input module, a touch sensor, and an illumination module. The touch sensor is disposed around the input module, senses a touch motion of the input module, and generates a touch signal according to the touch motion. The illumination module is disposed around the input module and coupled with the touch sensor. The illumination module is controlled to generate a light source to illuminate the input module according to the touch signal.

The invention further provides a touch illumination method, used at a portable electronic device. The portable electronic device has an input module, a touch sensor, and an illumination module. The touch illumination method includes the following steps. First, a touch motion of the input module is sensed. Second, a touch signal is generated according to the touch motion by the touch sensor. Third, a light source is generated according to the touch signal to illuminate the input module by the illumination module.

Via the portable electronic device or the method according to the invention, the user can turn on an illumination light source in an environment without sufficient light or in other proper environments in a touch way. As a result, even at night or at a place without sufficient light, the user can obtain enough brightness via the illumination light source and use the portable electronic device smoothly.

These and other features, aspects and advantages of the present invention will become better understood with regard to the following description, appended claims, and accompanying drawings.

### BRIEF DESCRIPTION OF THE DRAWINGS

FIG. 1 is a block diagram showing a portable electronic device with a touch illumination function according to an embodiment of the invention;

FIG. 2 is a schematic diagram showing a portable electronic device with a touch illumination function according to an embodiment of the invention;

FIG. 3A is a first schematic diagram showing a portable electronic device with a touch illumination function in use according to an embodiment of the invention;

FIG. 3B is a second schematic diagram showing a portable electronic device with a touch illumination function in use according to an embodiment of the invention;

FIG. 3C is a third schematic diagram showing a portable electronic device with a touch illumination function in use according to an embodiment of the invention; and

FIG. 4 is a flow diagram showing a touch illumination method.

### DETAILED DESCRIPTION

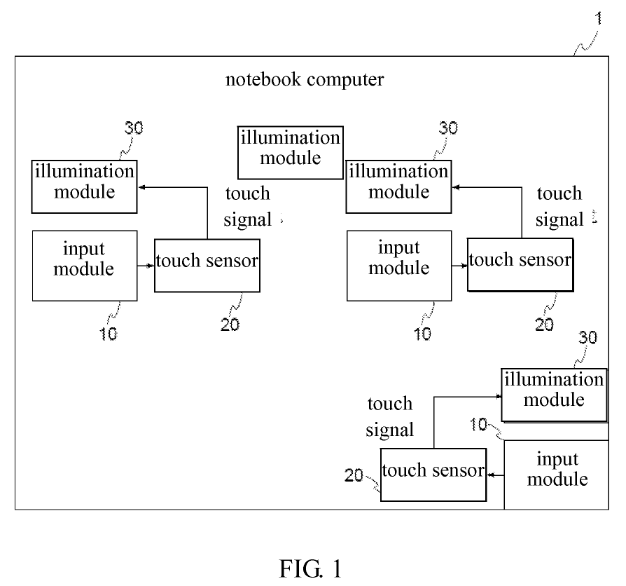

FIG. 1 is a block diagram showing a portable electronic device with a touch illumination function according to an embodiment of the invention. A portable electronic device 1 with the touch illumination function according to the invention includes an input module 10, a touch sensor 20, and an illumination module 30.

As shown in FIG. 1, three groups of the input modules 10, the touch sensors 20, and the illumination modules 30 are shown. The number of the input module 10, the touch sensor 20, and the illumination module 30 can be increased or decreased according to demands, the number is not limited to three.

Each touch sensor 20 is disposed around each input module 10, respectively, to sense a touch motion of each input module 10, and the corresponding touch sensor 20 generates a touch signal according to the touch motion. Since the touch sensor 20 is disposed around each input module 10, when the user touches any input module 10 of the portable electronic device 1, the touch sensor 20 coupled with the input module 10 generates the touch signal due to the touch of the user to facilitate subsequent use.

Each illumination module 30 is also disposed around each input module 10 and coupled with each touch sensor 20, respectively. When the touch sensor 20 generates the touch signal due to the touch of the user, the touch sensor 20 transmits the touch signal to the illumination module 30 coupled with the touch sensor 20. At the time, the touch signal can control the illumination module 30. For example, the touch signal controls the illumination module 30 to generate the light source to illuminate the corresponding input module 10.

A mode in which the touch sensor 20 generates the touch signal to control the illumination module 30 can be, but not limited to, one of the following modes. In a first mode, since a human body is an electricity conductor, when the human body touches the touch sensor 20, an inner voltage difference may be generated or changed to control the illumination module 30. In a second mode, the human body has a week bioelectric current, and the human body is equal to a capacitor in a circuit. Therefore, when the human body touches the touch sensor 20, an electrical parameter of the circuit such as capacitance is changed, a small current change is generated in the circuit, and then the current change is amplified via a an amplifying circuit to drive the illumination module 30 to work. In a third mode, a control loop is formed via a controller integrated circuit (IC) disposed in the portable electronic device and the touch sensor 20. When the human body touches the touch sensor 20, the touch sensor 20 generates a pulse signal (that is the touch signal in the invention) via a pulsating direct current to control the illumination module 30 to work.

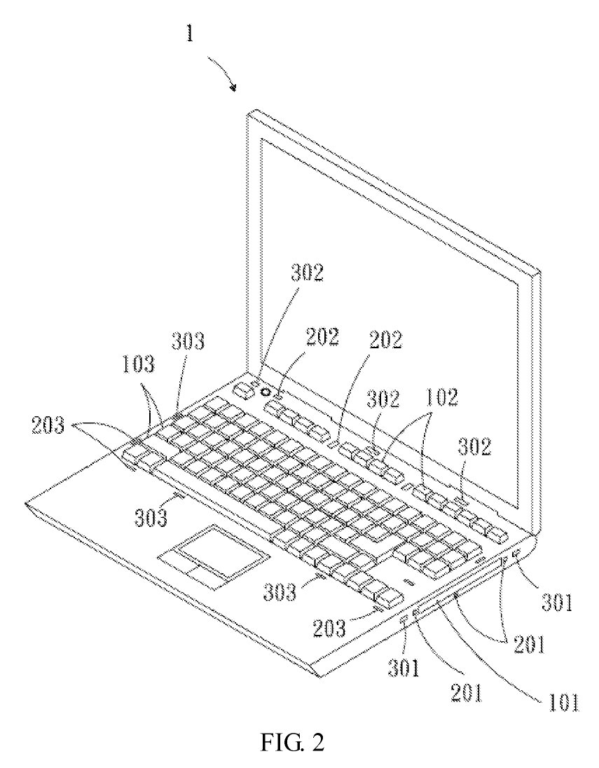

FIG. 2 is a schematic diagram showing a portable electronic device with a touch illumination function according to an embodiment of the invention. In this embodiment, a mode of realizing the input modules 101 to 103 with the touch illumination function in the portable electronic device 1 is illustrated with examples.

As shown in FIG. 2, the input module 101 may be a slot of the portable electronic device 1. To make the slot have the touch illumination function, a touch sensor 201 and an illumination module 301 are disposed around the slot. The input module 102 may be function keys of the portable electronic device 1. To make the function keys have the touch illumination function, the touch sensor 202 and the illumination module 302 are disposed around the function keys. The input module 103 may be a keyboard of the portable electronic device 1. To make the keyboard have the touch illumination function, a touch sensor 203 and an illumination module 303 are disposed around the keyboard.

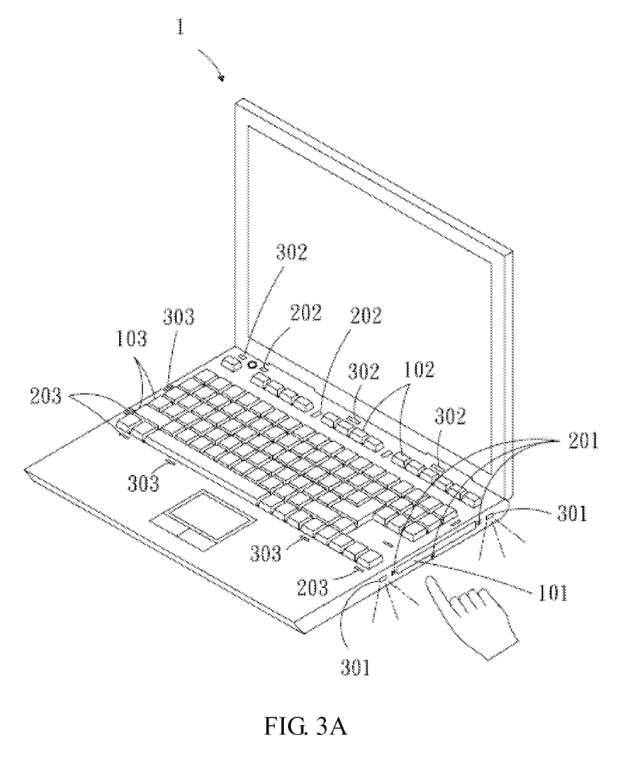

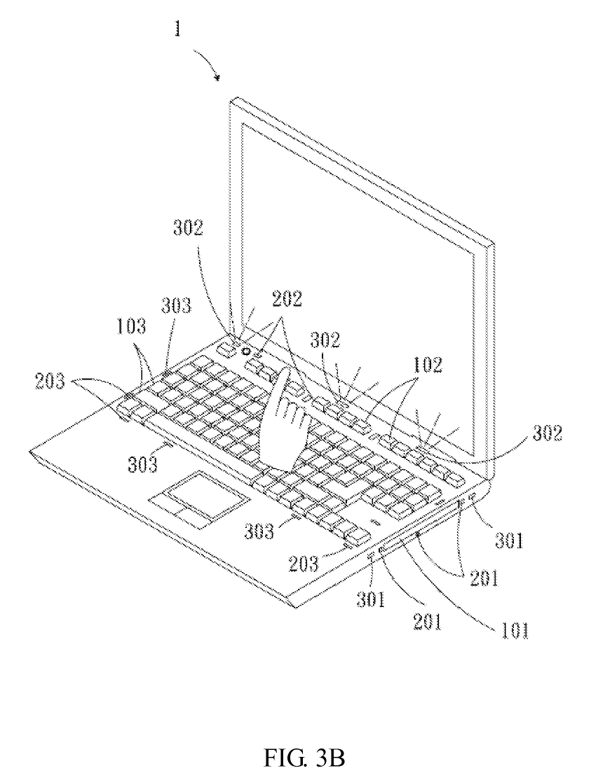

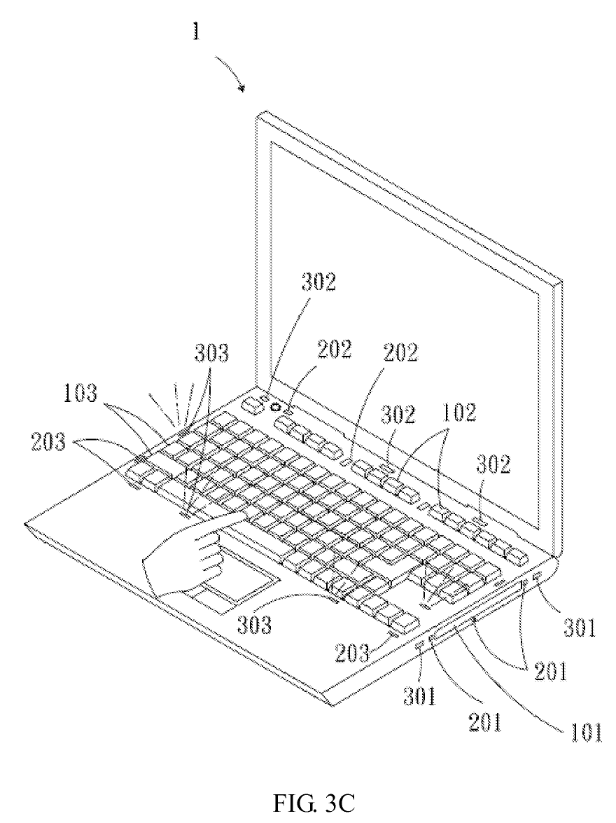

FIG. 3A˜3C are schematic diagrams showing a portable electronic device with a touch illumination function in use according to an embodiment of the invention. In FIG. 3A˜3C, the touch sensors 201 to 203 and the illumination modules 301 to 303 disposed around three different input modules 101-103 in FIG. 2, respectively, are taken as an example to illustrate touch illumination states of the portable electronic device 1.

As shown in FIG. 3A, if the user wants to connect a peripheral device with the slot (that is the input module 101) of the portable electronic device in an environment without sufficient light, and for example, the user connects an universal serial bus (USB) pocket drive with a USB port, the user may touch the input module 101 with her or his hand. Since the touch sensor 201 is disposed around the input module 101, when the user touches the input module 101 with her or his hand, the illumination module 301 coupled with the touch sensor 201 receives the touch signal transmitted by the touch sensor 201, and thus a light source is generated to illuminate the input module 101. Consequently, even in the environment without sufficient light, the user can lighten the illumination module 301 around the slot by lightly touching the periphery of the slot to allow the user to easily find a correct position of the slot in the dark.

As shown in FIG. 3B, if, the user wants to boot the portable electronic device 1 by pressing the power button (that is the input module 102) of the function keys in the environment without sufficient light, the user can touch the input module 102 with his hand to make the touch sensor 202 sense the touch motion of the input module 102 to generate the touch signal. As a result, the touch signal can control the illumination module 302 to generate the light source to illuminate the input module 102. Consequently, even in the environment without sufficient light, the user can lighten the illumination module 302 around function keys by lightly touching the periphery of the function keys to allow the user to easily identify every function key in the dark, and thus he finds a needed function key such as the power key to boot the portable electronic device 1.

As shown in FIG. 3C, if the user wants to edit a text via the keyboard (that is the input module 103) in the environment without sufficient light, the user can touch the input module 103 with his hand to make the touch sensor 203 sense the touch motion of the input module 103 to generate the touch signal. As a result, the touch signal can control the illumination module 302 to generate the light source to illuminate the input module 103. Consequently, even in the environment without sufficient light, the user can lighten the illumination module 303 around the keyboard by lightly touching the periphery of the keyboard to allow the user to easily identify each word and symbol on the keyboard in the dark environment to finish editing the text smoothly.

Additionally, a way in which the illumination module 30 receives the touch signal and generates the light source to illuminate the input module 10 may be various. For example, after the illumination module 30 receives the touch signal, the light source may be turned on for a predetermined time. For example, after the user touches the slot of the input module 10, the corresponding illumination module 30 is controlled to turn on the light source for ten seconds. Then, the user can find the correct position of the slot to connect the peripheral device and the portable electronic device 1 in the predetermined time with ten seconds. After ten seconds, the light source of the illumination module 30 is automatically turned off. The predetermined time during which the light source is turned on can be set by the user according to his demands or the computer system.

In another situation, when the illumination module 30 receives the touch signal, it can continuously turn on the light source and turn off the light source after the illumination module receiving the touch signal again. Similarly, the slot is taken as an example of the input module 10. As a result, once the user touches the slot of the input module 10, the corresponding illumination module 30 turns on the light source immediately. When the user finds the correct position of the slot and connects the peripheral device with the portable electronic device 1, or the user thinks that he does not need to use the light source, the user can touch the slot again, and then the light source corresponding to the illumination module 30 of the slot is turned off.

Furthermore, to make the light source generated by the illumination module 30 illuminate the input module 10 clearly, the input module 10 may have a transparent portion via which the illumination module 30 may emit the light source. For example, the keyboard may be designed to be in a hollow transparent mode. Then, when the illumination module 30 corresponding to the keyboard is lightened due to the touch, the user can easily and clearly identify the each letter and the symbol marked on the keyboard.

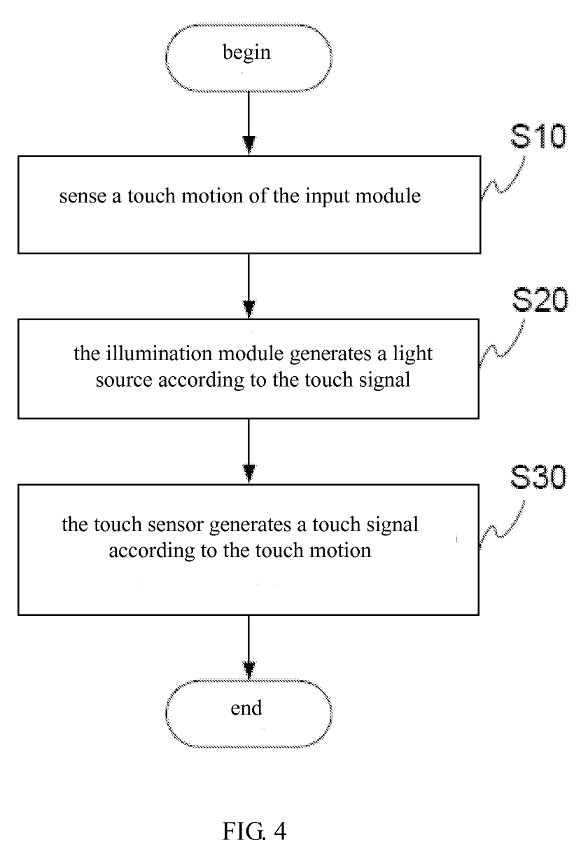

FIG. 4 is a flow diagram showing a touch illumination method. The touch illumination method is used at a portable electronic device. The portable electronic device has an input module, a touch sensor, and an illumination module. The touch illumination method includes the following steps.

At step S10, a touch motion of the input module is sensed.

At step S20, the touch sensor generates a touch signal according to the touch motion.

At step S30, the illumination module generates a light source according to the touch signal to illuminate the input module.

Besides above steps, the touch illumination method may include the following steps. The light source is turned on for a predetermined time after the illumination module receives the touch signal, or the light source is continuously turned on after the illumination module receives the touch signal, and the light source is turned off after the illumination module receiving the touch signal again.

While the present invention has been described by the way of example and in terms of the preferred embodiments, it is to be understood that the invention is not limited to the disclosed embodiments. To the contrary, it is intended to cover various modifications and similar arrangements. Therefore, the scope of the appended claims should be accorded the broadest interpretation so as to encompass all such modifications and similar arrangements.

What is claimed is:

1. A portable electronic device with a touch illumination function, comprising:
an input module;
a touch sensor disposed around the input module, sensing a touch motion of the input module, and generating a touch signal according to the touch motion; and
an illumination module disposed around the input module and coupled with the touch sensor, wherein the illumination module is controlled to generate a light source to illuminate the input module according to the touch signal.

2. The portable electronic device according to claim 1, wherein the illumination module receives the touch signal and turns on the light source for a predetermined time.

3. The portable electronic device according to claim 1, wherein the illumination module receives the touch signal and turns on the light source, and the illumination module turns off the light source after receiving the touch signal again.

4. The portable electronic device according to claim 1, wherein the input module is chosen from a function key, a keyboard, a slot, and a combination of the above-mentioned.

5. The portable electronic device according to claim 1, wherein the input module has a transparent portion, and the illumination module transmits light via the transparent portion.

6. A touch illumination method, applied to a portable electronic device, wherein the portable electronic device comprises an input module, a touch sensor, and an illumination module, the touch illumination method comprising:
sensing a touch motion of the input module;
generating a touch signal according to the touch motion by the touch sensor; and
generating a light source according to the touch signal by the illumination module.

7. The touch illumination method according to claim 6, further comprising:
turning on the light source for a predetermined time after the illumination module receives the touch signal.

8. The touch illumination method according to claim 6, further comprising:
continuously turning on the light source after the illumination module receives the touch signal; and
turning off the light source after the illumination module receiving the touch signal again.
